(19) United States
(12) Patent Application Publication
(10) Pub. No.: US 2026/0282486 A1
(43) Pub. Date: Sep. 17, 2026

(54) BACKSIDE NS DEPOPULATION FOR FORKSHEET TRANSISTORS

(71) Applicant: INTERNATIONAL BUSINESS MACHINES CORPORATION, ARMONK, NY (US)

(72) Inventors: Xiaoli He, Clifton Park, NY (US); Lijuan Zou, Albany, NY (US); Ruilong Xie, Niskayuna, NY (US); Tao Li, Slingerlands, NY (US); Jingyun Zhang, Albany, NY (US)

(21) Appl. No.: 19/079,895

(22) Filed: Mar. 14, 2025

(51) Int. Cl. H10D 64/23; H10D 30/00; H10D 84/83

(52) U.S. Cl. CPC H10D 64/254; H10D 30/507; H10D 84/833

(57) ABSTRACT

A microelectronic structure that includes a forksheet nanosheet transistor that includes a source/drain a backside contact located on the backside surface of the source/drain and a backside spacer plug located on a first side of the backside contact.

### BACKGROUND

The present invention generally relates to the field of microelectronics, and more particularly to forming connections to power rails located on the same level.

Nanosheet is the lead device architecture in continuing CMOS scaling. However, nanosheet technology has shown issues when scaling down such that as the devices becoming smaller and closer together, they are interfering with each other. With the number of devices being fitted in a smaller area it is becoming harder to fix mis-alignment errors which can lead to defects in downstream processing.

### BRIEF SUMMARY

Additional aspects and/or advantages will be set forth in part in the description which follows and, in part, will be apparent from the description, or may be learned by practice of the invention.

A microelectronic structure that includes a forksheet nanosheet transistor that includes a source/drain a backside contact located on the backside surface of the source/drain and a backside spacer plug located on a first side of the backside contact.

A microelectronic device includes a forksheet nanosheet transistor that includes a source/drain, a plurality of first channel layers and a plurality of second channel layers. A dielectric pillar located between the plurality of first channel layers and the plurality of second channel layers. A backside contact located on the backside surface of the source/drain. A backside spacer plug located on a first side of the dielectric pillar.

A microelectronic device includes a forksheet nanosheet transistor that includes a source/drain, a plurality of first channel layers and a plurality of second channel layers. A dielectric pillar located between the plurality of first channel layers and the plurality of second channel layers. A backside contact located on the backside surface of the source/drain. A backside spacer plug located on a first side of the backside contact and a second backside spacer plug located on a first side of the dielectric pillar.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of forksheet nanosheet transistors, in accordance with the embodiment of the present invention.

FIG. 2 illustrates a cross-section X of the forksheet nanosheet FET after initial frontside processing, in accordance with the embodiment of the present invention.

FIG. 3 illustrates a cross-section Y1 of the gate region of the forksheet nanosheet FET after initial frontside processing, in accordance with the embodiment of the present invention.

FIG. 4 illustrates a cross-section Y2 of the source/drain region of the forksheet nanosheet transistor after initial frontside processing, in accordance with the embodiment of the present invention.

FIG. 5 illustrates a cross-section X of the forksheet nanosheet FET after initial backside processing, in accordance with the embodiment of the present invention.

FIG. 6 illustrates a cross-section Y1 of the gate region of the forksheet nanosheet FET after initial backside processing, in accordance with the embodiment of the present invention.

FIG. 7 illustrates a cross-section Y2 of the source/drain region of the forksheet nanosheet transistor after initial backside processing, in accordance with the embodiment of the present invention.

FIG. 8 illustrates a cross-section X of the forksheet nanosheet FET after additional backside processing, in accordance with the embodiment of the present invention.

FIG. 9 illustrates a cross-section Y1 of the gate region of the forksheet nanosheet FET after additional backside processing, in accordance with the embodiment of the present invention.

FIG. 10 illustrates a cross-section Y2 of the source/drain region of the forksheet nanosheet transistor after additional backside processing, in accordance with the embodiment of the present invention.

FIG. 11 illustrates a cross-section X of the forksheet nanosheet FET after formation of the lithography layer, in accordance with the embodiment of the present invention.

FIG. 12 illustrates a cross-section Y1 of the gate region of the forksheet nanosheet FET after the lithography layer, in accordance with the embodiment of the present invention.

FIG. 13 illustrates a cross-section Y2 of the source/drain region of the forksheet nanosheet transistor after the lithography layer, in accordance with the embodiment of the present invention.

FIG. 14 illustrates a cross-section X of the forksheet nanosheet FET after formation of a sacrificial layer and initial pattering of the lithography layer, in accordance with the embodiment of the present invention.

FIG. 15 illustrates a cross-section Y1 of the gate region of the forksheet nanosheet FET after formation of a sacrificial layer and initial pattering of the lithography layer, in accordance with the embodiment of the present invention.

FIG. 16 illustrates a cross-section Y2 of the source/drain region of the forksheet nanosheet transistor after formation of a sacrificial layer and initial pattering of the lithography layer, in accordance with the embodiment of the present invention.

FIG. 17 illustrates a cross-section X of the forksheet nanosheet FET after formation of a backside spacer layer, in accordance with the embodiment of the present invention.

FIG. 18 illustrates a cross-section Y1 of the gate region of the forksheet nanosheet FET after formation of a backside spacer layer, in accordance with the embodiment of the present invention.

FIG. 19 illustrates a cross-section Y2 of the source/drain region of the forksheet nanosheet transistor after formation of a backside spacer layer, in accordance with the embodiment of the present invention.

FIG. 20 illustrates a cross-section X of the forksheet nanosheet FET after removal of excess backside spacer layer, in accordance with the embodiment of the present invention.

FIG. 21 illustrates a cross-section Y1 of the gate region of the forksheet nanosheet FET after removal of excess backside spacer layer, in accordance with the embodiment of the present invention.

FIG. 22 illustrates a cross-section Y2 of the source/drain region of the forksheet nanosheet transistor after removal of excess backside spacer layer, in accordance with the embodiment of the present invention.

FIG. 23 illustrates a cross-section X of the forksheet nanosheet FET after formation of the extended trench, in accordance with the embodiment of the present invention.

FIG. 24 illustrates a cross-section Y1 of the gate region of the forksheet nanosheet FET after formation of the extended trench, in accordance with the embodiment of the present invention.

FIG. 25 illustrates a cross-section Y2 of the source/drain region of the forksheet nanosheet transistor after formation of the extended trench, in accordance with the embodiment of the present invention.

FIG. 26 illustrates a cross-section X of the forksheet nanosheet FET after depopulation of a channel layer, in accordance with the embodiment of the present invention.

FIG. 27 illustrates a cross-section Y1 of the gate region of the forksheet nanosheet FET after depopulation of a channel layer, in accordance with the embodiment of the present invention.

FIG. 28 illustrates a cross-section Y2 of the source/drain region of the forksheet nanosheet transistor after depopulation of a channel layer, in accordance with the embodiment of the present invention.

FIG. 29 illustrates a cross-section X of the forksheet nanosheet FET after removal of the lithography layer and formation of the backside interlayer dielectric layer, in accordance with the embodiment of the present invention.

FIG. 30 illustrates a cross-section Y1 of the gate region of the forksheet nanosheet FET after removal of the lithography layer and formation of the backside interlayer dielectric layer, in accordance with the embodiment of the present invention.

FIG. 31 illustrates a cross-section Y2 of the source/drain region of the forksheet nanosheet transistor after removal of the lithography layer and formation of the backside interlayer dielectric layer, in accordance with the embodiment of the present invention.

FIG. 32 illustrates a cross-section X of the forksheet nanosheet FET after removal of the placeholders and formation of the backside contacts, in accordance with the embodiment of the present invention.

FIG. 33 illustrates a cross-section Y1 of the gate region of the forksheet nanosheet FET after removal of the placeholders and formation of the backside contacts, in accordance with the embodiment of the present invention.

FIG. 34 illustrates a cross-section Y2 of the source/drain region of the forksheet nanosheet transistor after removal of the placeholders and formation of the backside contacts, in accordance with the embodiment of the present invention.

FIG. 35 illustrates a cross-section X of the forksheet nanosheet FET after formation and patterning of a lithography layer and the removal of one or more backside contacts, in accordance with the embodiment of the present invention.

FIG. 36 illustrates a cross-section Y1 of the gate region of the forksheet nanosheet FET after formation and patterning of a lithography layer and the removal of one or more backside contacts, in accordance with the embodiment of the present invention.

FIG. 37 illustrates a cross-section Y2 of the source/drain region of the forksheet nanosheet transistor after formation and patterning of a lithography layer and the removal of one or more backside contacts, in accordance with the embodiment of the present invention.

FIG. 38 illustrates a cross-section X of the forksheet nanosheet FET after additional backside processing, in accordance with the embodiment of the present invention.

FIG. 39 illustrates a cross-section Y1 of the gate region of the forksheet nanosheet FET after additional backside processing, in accordance with the embodiment of the present invention.

FIG. 40 illustrates a cross-section Y2 of the source/drain region of the forksheet nanosheet transistor after additional backside processing, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards correcting a misaligned error that occurred during a process to depopulate a forksheet transistor. During the backside depopulation process a lithography layer or an OPL layer is formed on the backside region. A trench is formed in the lithography layer, where in a perfect alignment will place the trench in a position aligned with the channels that will be depopulated. However, the formation of the trench can be misaligned and with decrease in scale, the misalignment can lead to defects forming during downstream processing. The misalignment can occur on the X-axis, the Y-axis, or on both axis. The present invention is directed towards correcting misalignment errors caused during the trench formation process, to prevent downstream defects. After the trench is formed a spacer layer is formed in the trench by, for example, Atomic Layer Deposition. The spacer layer fills in any voids caused by the misalignment where the spacer layer that fills in these voids will be referred to as spacer plugs. During the depopulation process the lithography layer is etched/patterned to expose the channel layer to be removed. If the misaligned areas were not filled in, then the etching/patterning would also remove material from the misaligned areas. The spacer plug prevents the etching process from removing lithography layer material from the misaligned areas.

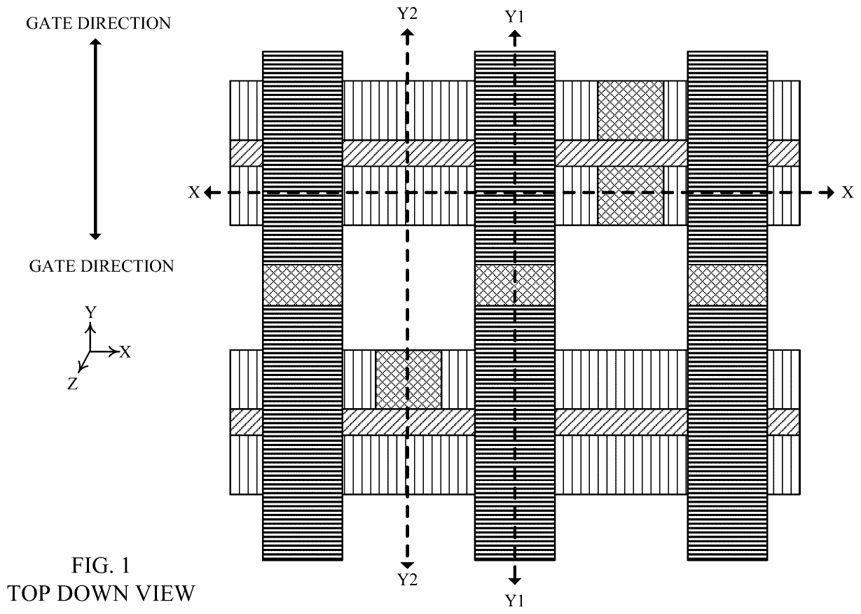

FIG. 1 illustrates a top-down view of forksheet nanosheet transistors, in accordance with the embodiment of the present invention. Cross-section X is a cross-section that extends through the forksheet nanosheet FET. Cross-section Y1 is a cross-section through a gate region that spans across the first and second forksheet transistors or forksheet field-effect-transistors. Cross-section Y2 is a cross-section through a source/drain region that spans across the forksheet transistors or forksheet field-effect-transistors. Cross-section X are perpendicular to the gate direction and cross-section Y1 and Y2 are parallel to the gate direction.

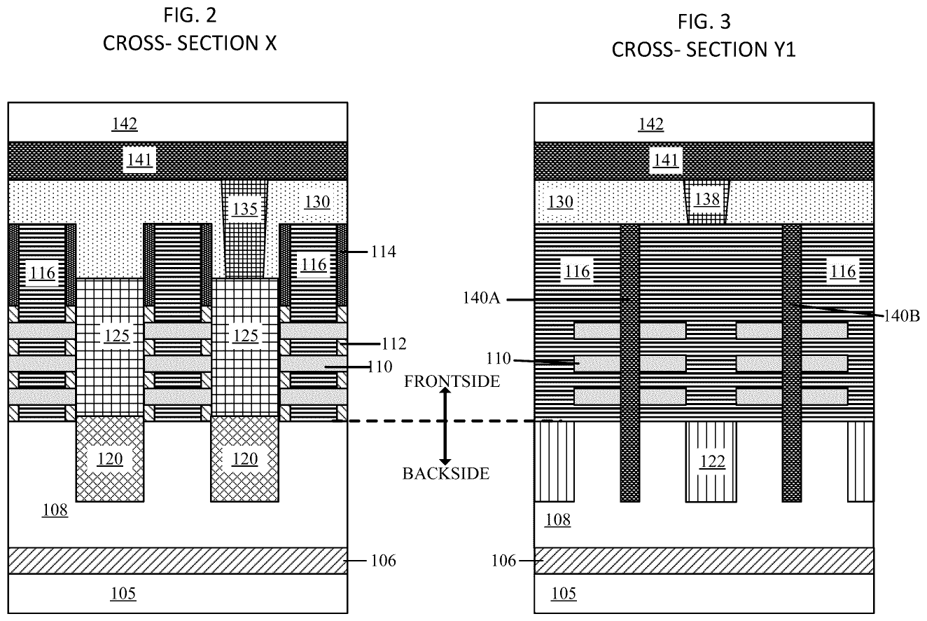

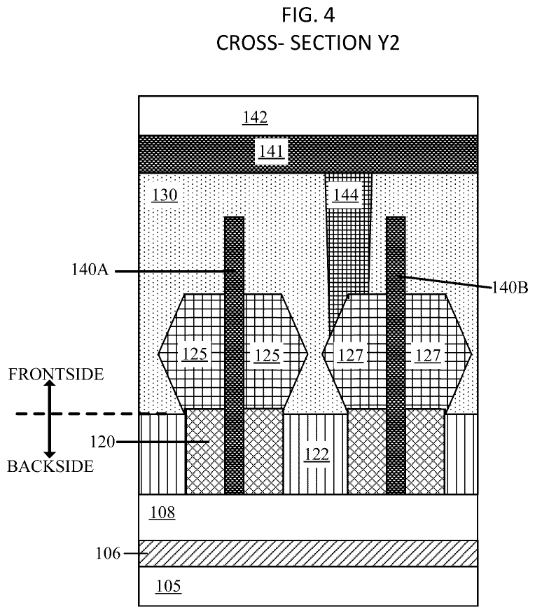

Referring now to FIGS. 2, 3, and 4, illustrate a structure is shown during an intermediate step of a method of fabrication after initial frontside processing. FIGS. 2, 3, and 4 illustrate a different cross-sections of the forksheet nanosheet FET that include a first substrate 105, an etch stop 106, a second substrate 108, placeholders 120, a plurality of channel layers 110, inner spacers 112, a first source/drain 125, a second source/drain 127, gate 116, gate spacer 114, a frontside interlayer dielectric layer 130, a first frontside source/drain contact 135, a frontside gate contact 138, a second frontside contact 144, a first dielectric pillar 140A, a second dielectric pillar 140B, shallow trench isolation layer 122, a frontside interconnect 141, and a carrier wafer 142.

The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein.

Gate 116 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

The first source/drain 125, and the third source/drain 127, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

A frontside interconnect 141 is formed on a frontside interlayer dielectric layer 130, a first frontside source/drain contact 135, a frontside gate contact 138, and a second frontside contact 144. The frontside interconnect 141 can be comprised of one or more layers, one or more metal lines, one or more vias, or any combination thereof. The carrier wafer 142 is formed on the frontside interconnect 141, where the carrier wafer 142 allows for the flipping of the forksheet nanosheet transistor for backside processing.

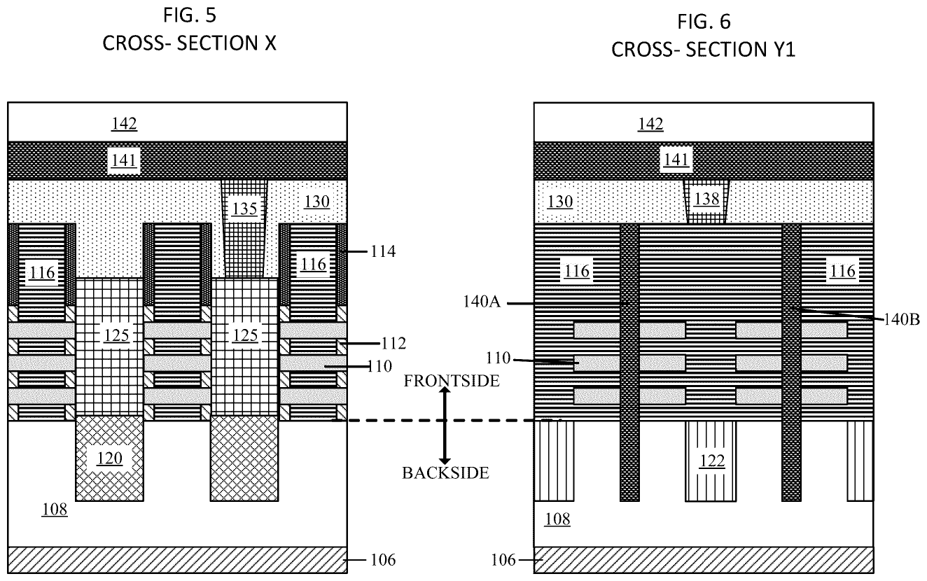

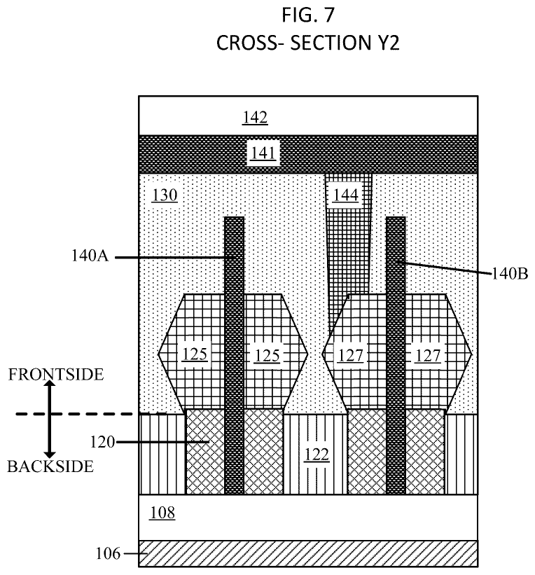

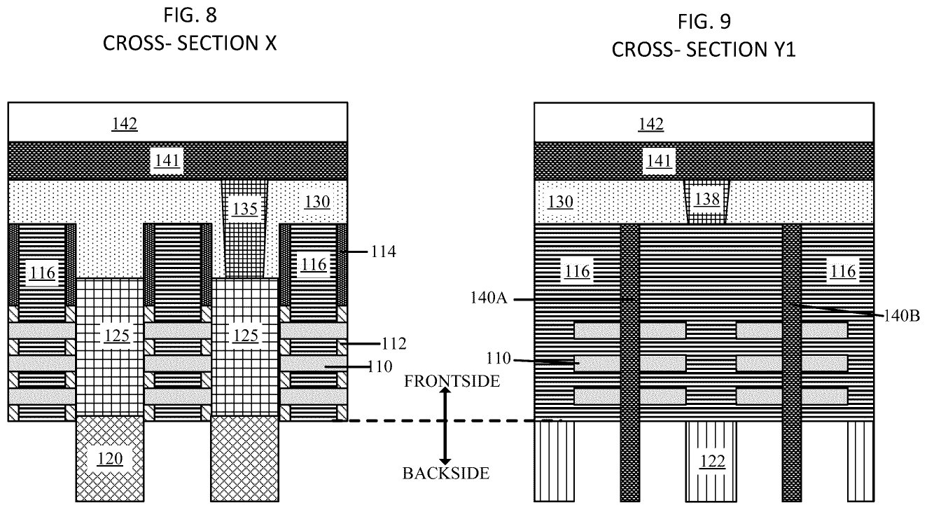

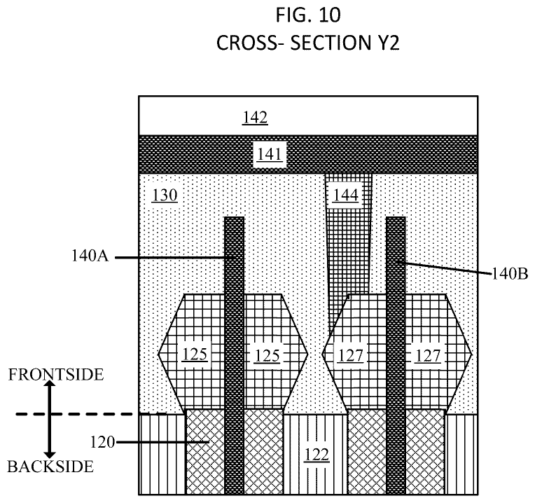

FIGS. 5, 6, and 7 illustrate the processing stage after initial backside processing. The wafer that contains the forksheet nanosheet transistors is flipped over for backside processing. The Figures do not illustrate the flipping over of the forksheet, but the Figures do indicate the frontside region and the backside region. The first substrate 105 is removed to expose the etch stop layer 106. FIGS. 8, 9, and 10 illustrate the processing stage after additional backside processing. The etch stop layer 106 and the second substrate 108 are removed to expose a backside surface of the gate 116, the placeholders 120, the shallow trench isolation layer 122, the first dielectric pillar 140A, and the second dielectric pillar 140B.

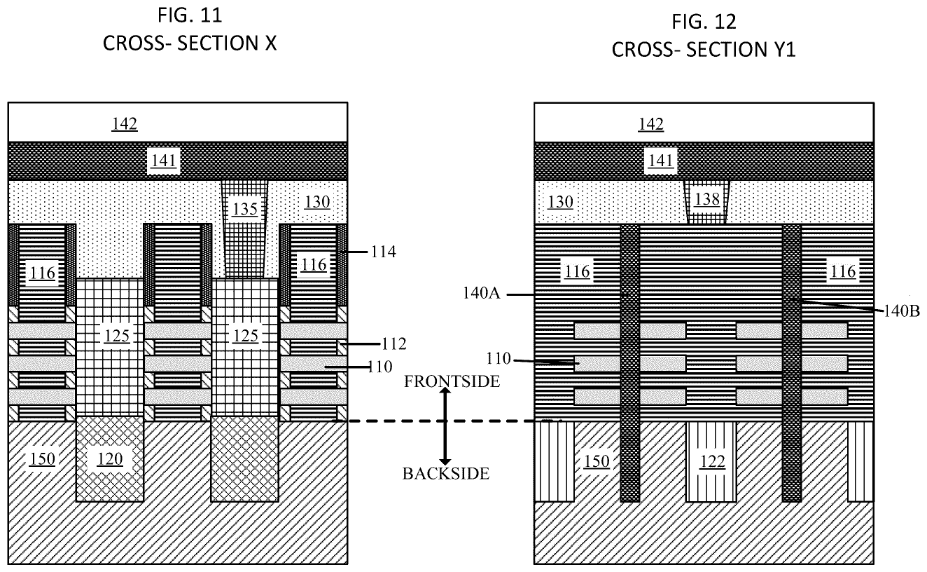

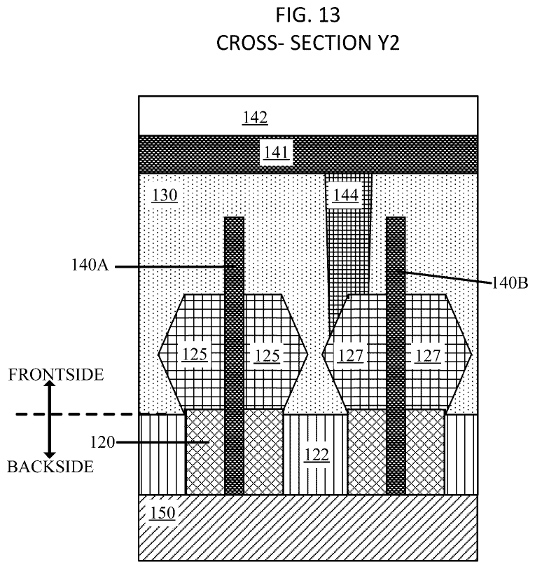

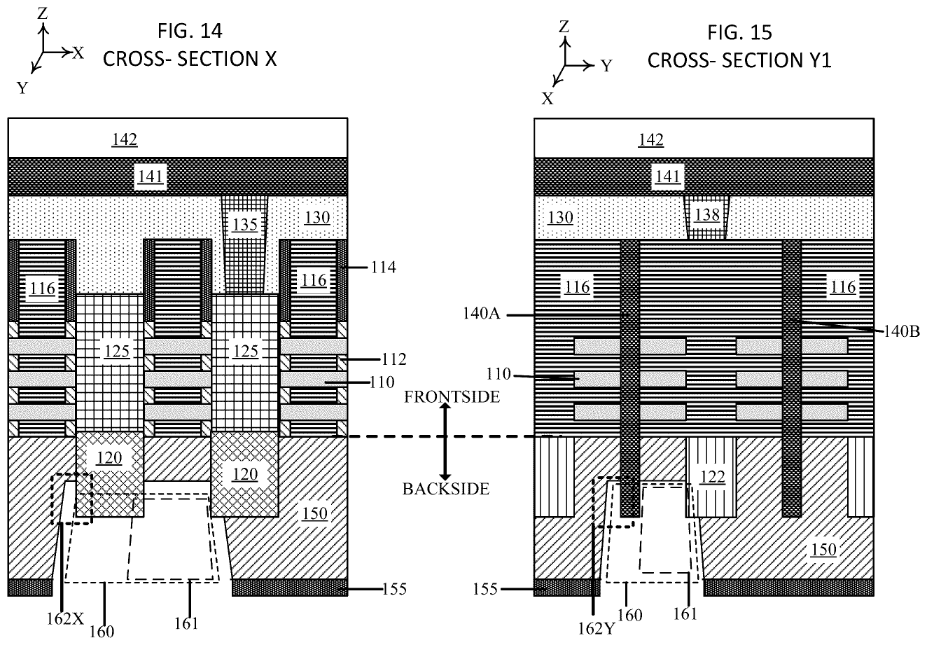

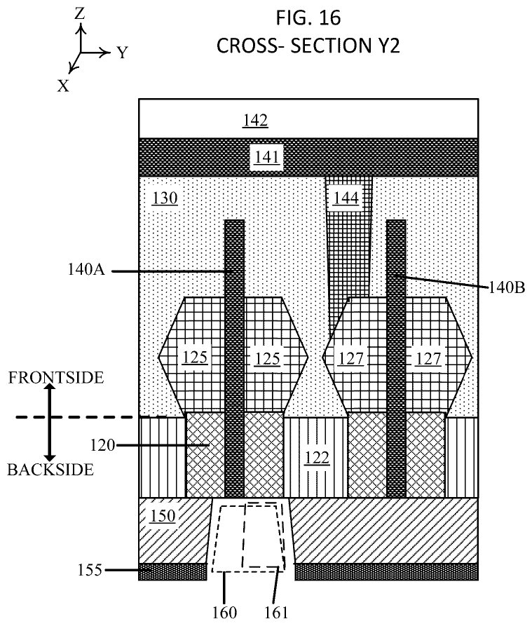

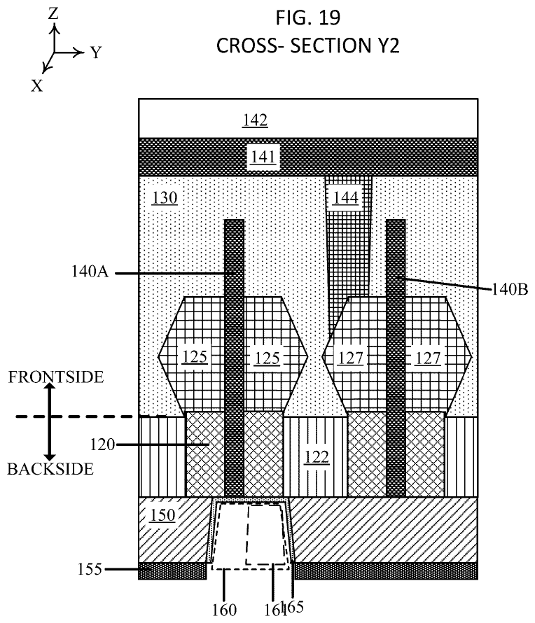

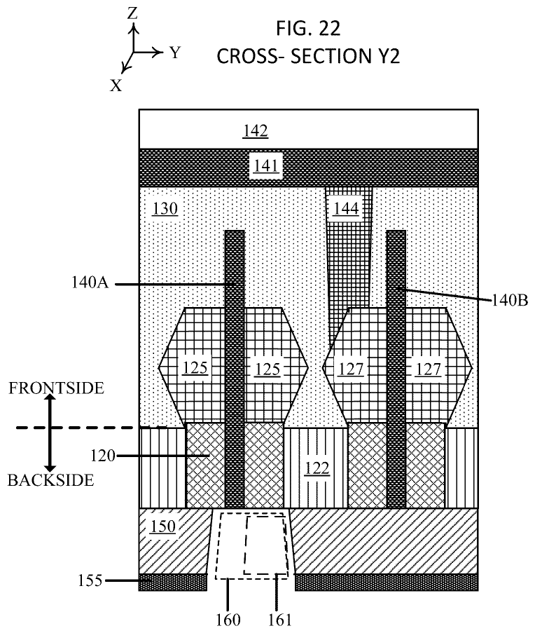

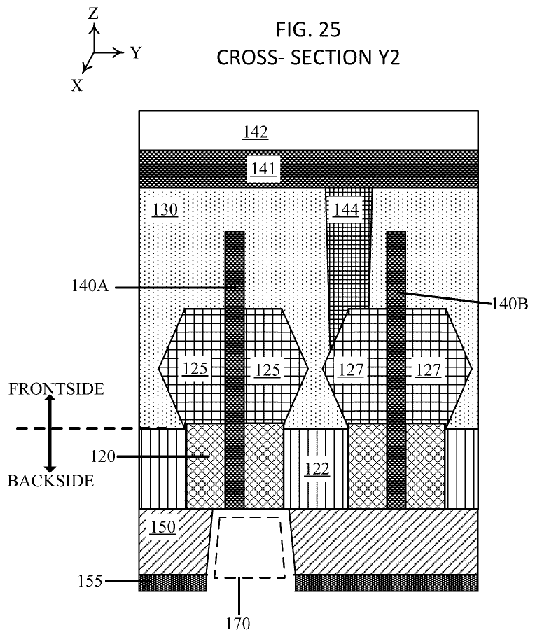

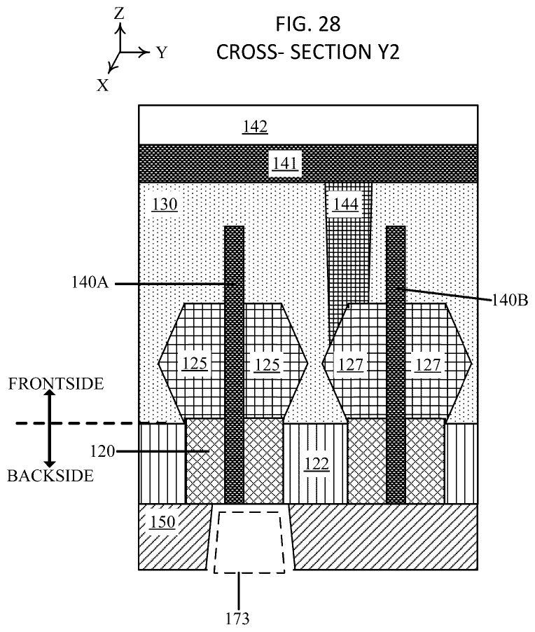

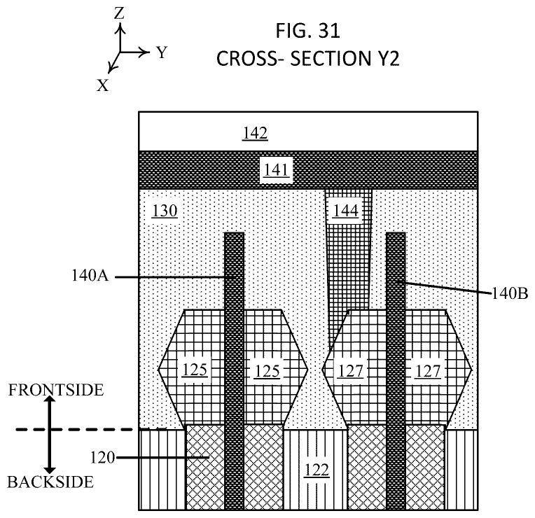

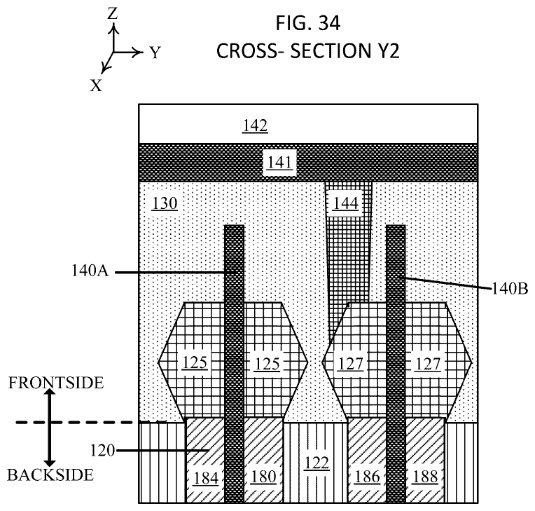

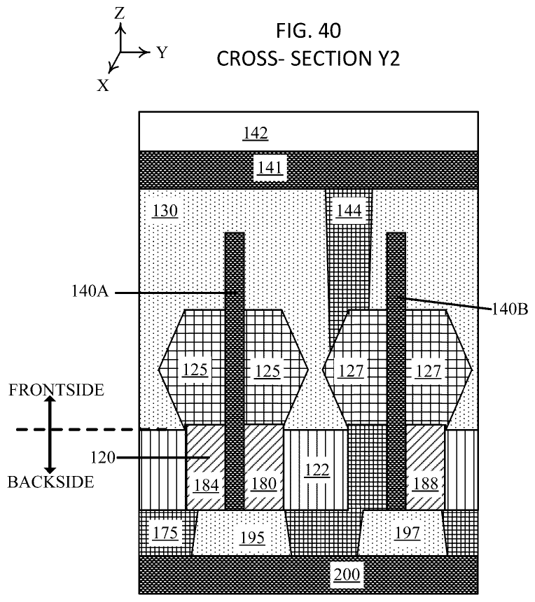

FIGS. 11, 12, and 13 illustrate the processing stage after the formation of lithography layer 150. The lithography layer 150 is formed on the backside region to cover the exposed elements of the gate 116, the placeholders 120, the shallow trench isolation layer 122, the first dielectric pillar 140A, and the second dielectric pillar 140B. The lithography layer 150 can be for example, an optical planarization layer (OPL) or a different type of lithography material. FIGS. 14, 15, and 16 illustrate the processing stage after formation of a sacrificial layer 155 and an initial patterning of the lithography layer 150. A sacrificial layer 155 is formed on the backside surface of the lithography layer 150. The sacrificial layer 155 can be comprised of, for example, SiARC. The sacrificial layer 155 and the lithography layer 150 are patterned to form an initial trench 160. FIGS. 14-40 illustrate the scenario when the initial trench 160 is misaligned in the X-axis and the Y-axis. If the initial trench was perfectly aligned as emphasized by dashed box 161, then the perfectly aligned trench 161 would only expose the lithography layer 150 located between the two placeholders 120 along the X-axis (illustrated in FIG. 14) and would only be located on one side of the first dielectric pillar 140A along the Y-axis. The misaligned initial trench 160 as illustrated in FIGS. 14-16, illustrate the scenario where the initial trench 160 is laterally or horizontally (in the X-Axis and/or Y-axis) shifted to expose an area of the lithography layer 150 that should not have been exposed as emphasized by dashed boxes 162X and 162Y. The misalignment can occur on multiple axis (e.g., in the X-Axis and Y-axis) as illustrated in the current figures or the misalignment can occur on one axis (e.g., in the X-Axis or Y-axis).

Dash box 162X in FIG. 14 illustrates the scenario where the initial trench 160 was horizontally shifted (i.e., misalignment in the X-axis) to expose the lithography layer 150 on multiple sides of the placeholder 120. Dash box 162Y in FIG. 15 illustrates the scenario where the initial trench 160 was horizontally shifted (i.e., misalignment in the Y-axis) to expose the lithography layer 150 on multiple sides of the first dielectric pillar 140A. The present invention is directed towards depopulating a channel layer 110 from the forksheet transistor. The depopulation process requires the initial trench 160 to be extended towards the backside region of one of the channel layers 110. However, because of the misalignment (in the X-Axis and/or Y-axis) of the initial trench 160 the lithography layer 150 will be etched in unwanted areas that can lead to defects being formed.

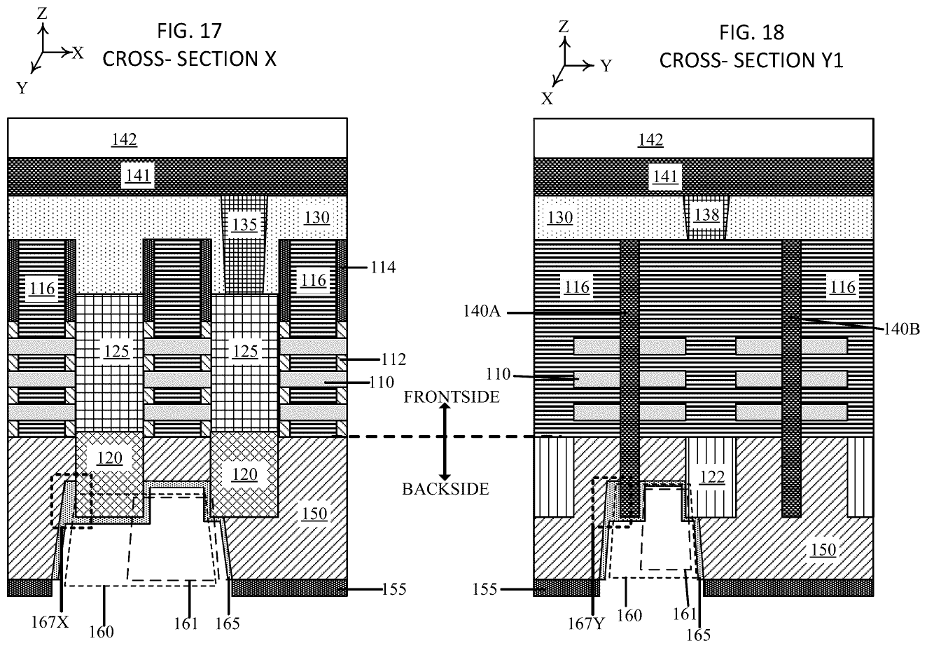

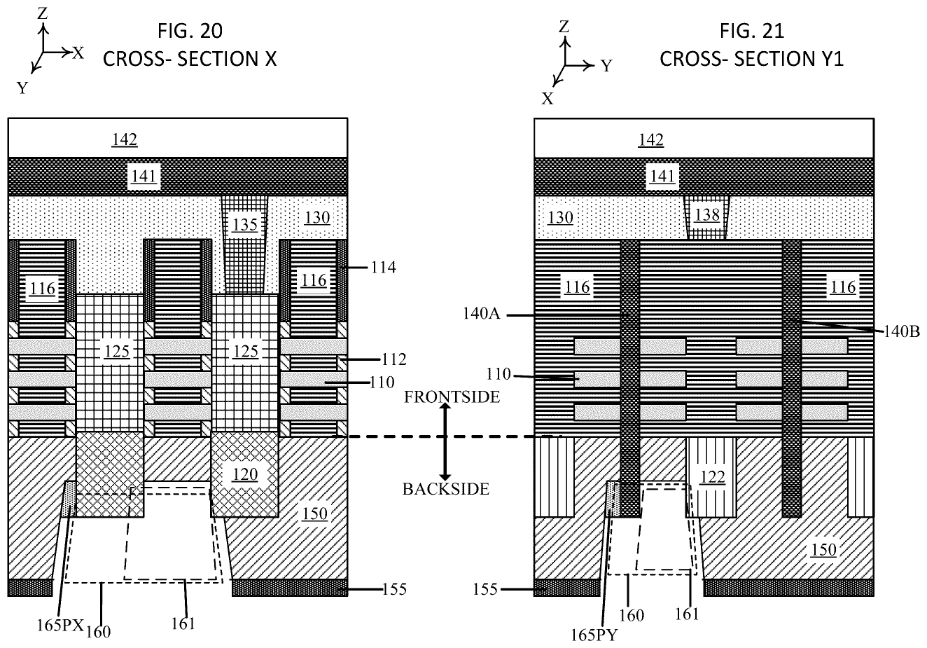

FIGS. 17, 18, and 19 illustrate the processing stage after the formation of a backside spacer layer 165. A backside spacer layer 165 is formed by, for example, atomic layer deposition, on the exposed surfaces of the initial trench 160, the exposed surface of the placeholder 120, and along the exposed surface of the first dielectric pillar 140A. The backside spacer layer 165 fills in the areas created by the misalignment of the initial trench 160 as emphasized by dashed box 167X and 167Y. The misaligned areas are relatively small, so the backside spacer layer 165 quickly pinches off/seals these areas as emphasized by dashed box 167X and 167Y. FIGS. 20, 21, and 22 illustrate the processing stage after removal of excess backside spacer layer 165 material. Excess backside spacer layer 165 is removed by, for example, an isotropic wet etch, to form backside spacer plugs 165PX and 165PY. Since the backside spacer layer 165 has a relatively thin thickness, etch time to remove the excess material is relatively short. The material that was formed in the misaligned areas, as emphasized by dashed boxes 167X, 167Y, remains relatively protected from the etching process by the lithography layer 150, the placeholder 120, and by the first dielectric pillar 140A. Therefore, a portion of the backside spacer layer 165 remains to form the backside spacer plugs 165PX and 165PY. The backside spacer plugs 165PX and 165PY fills in the misaligned areas of the initial trench 160. The present figures illustrate the situation where there was a misalignment in multiple axis, i.e., X-axis and Y-axis, but the misalignment could occur in only one axis, i.e., X-axis or Y-axis. One of ordinary skill in the art would realize that only one backside spacer plug 165PX or 165PY would be present when the misalignment occurred in only one axis.

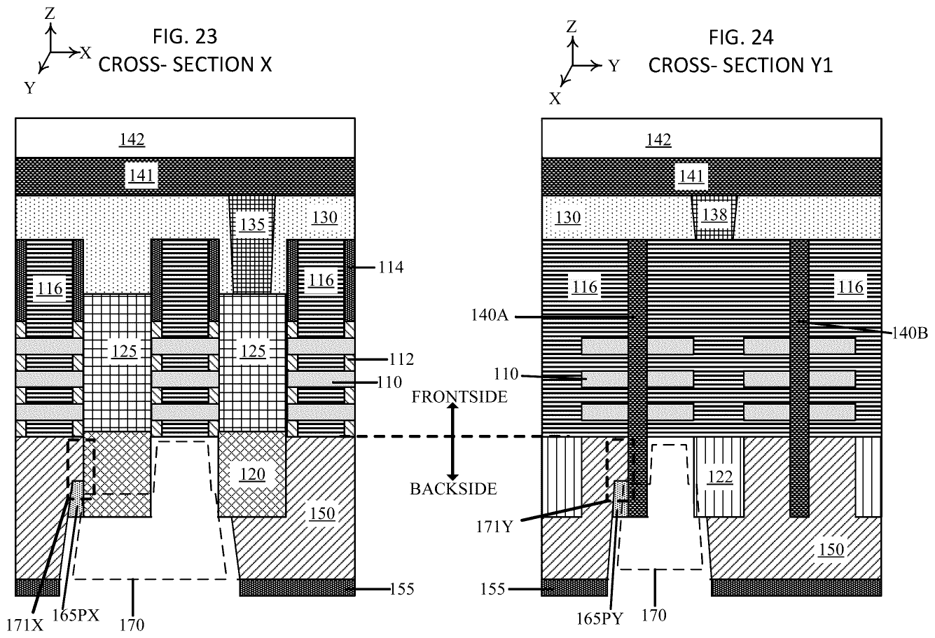

FIGS. 23, 24, and 25 illustrate the processing stage after the formation of the extended trench 170. The bottom boundary (i.e., the boundary closer to the backside surface of the gate 116) of initial trench 160 is extend by etching the exposed lithography layer 150 to form the extended trench 170. If the backside spacer plug 165PX (X-axis misalignment) was not present, then the etching of the lithography layer 150 would occur in an unwanted area as emphasized by dash box 171X. If the backside spacer plug 165PY (Y-axis misalignment) was not present, then the etching of the lithography layer 150 would occur in an unwanted area as emphasized by dash box 171Y. This unwanted etch (as emphasized by dash box 171X and 171Y) of the lithography layer 150 would have exposed surface of gates 116 that were not meant to be exposed. The backside spacer plugs 165PX and 165PY prevent the unwanted areas (as emphasized by dash box 171X and 171Y) of the lithography layer 150 from being etched. The extended trench 170 exposes a backside surface of gate 116 of one of the forksheet transistor.

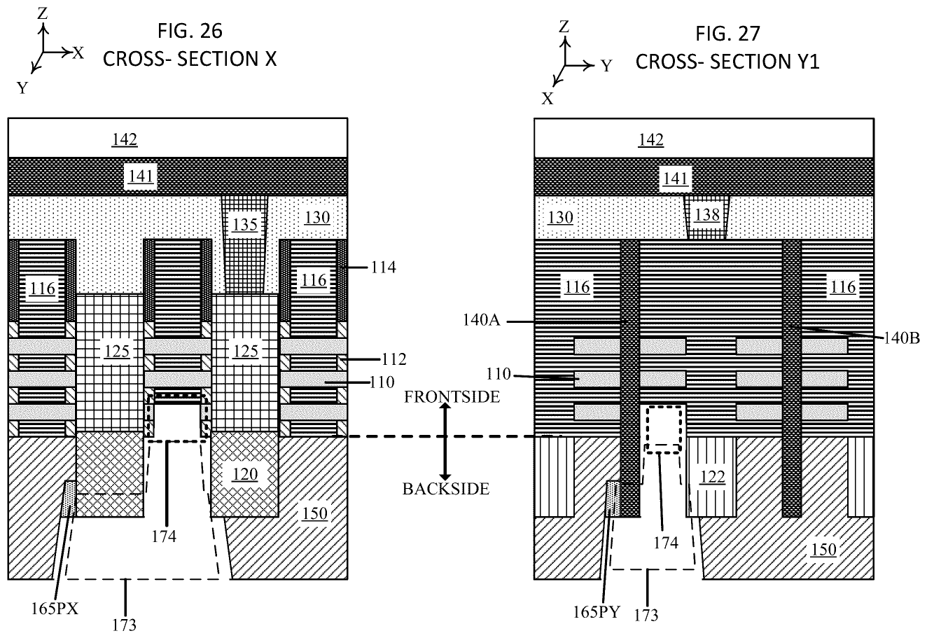

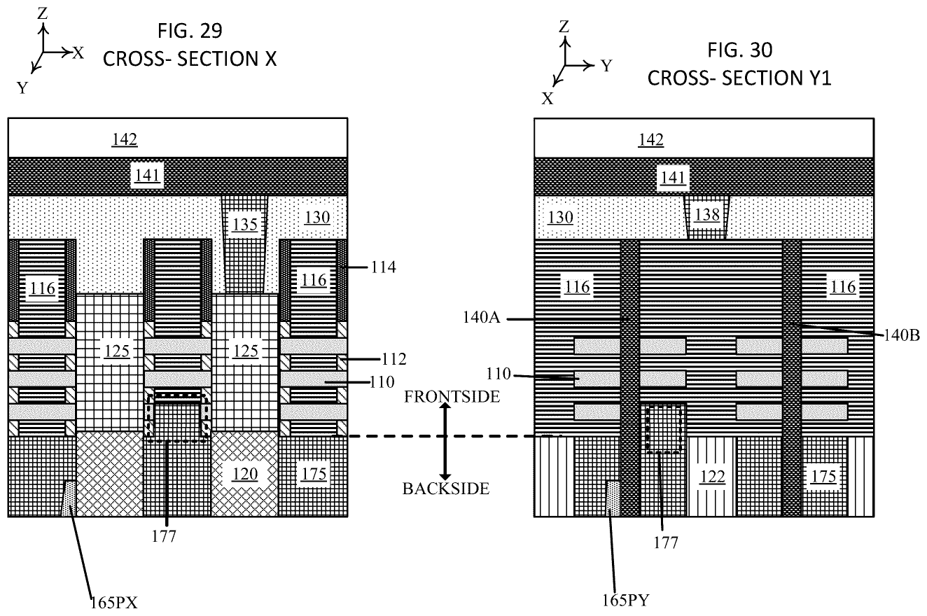

FIGS. 26, 27, and 28 illustrate the processing stage after depopulation of a channel layer 110. Gate 116 and one of the channel layers 110 are etched to depopulate a side of the forksheet transistor as emphasized by dashed box 174. A center portion of one of the channel layers 110 is removed and the end portions of the channel layer 110 remain sandwich between inner spacers 112, as emphasized by dashed box 174. FIGS. 29, 30, and 31 illustrate the processing stage after removal of the lithography layer 150 and the sacrificial layer 155, and formation of the backside interlayer dielectric layer 175. The lithography layer 150 and the sacrificial layer 155 are removed and a backside interlayer dielectric layer 175 is formed on the exposed surfaces. The backside interlayer dielectric layer 175 fills the area of the depopulated channel layer as emphasized by dashed box 177. The backside region is planarized to expose the backside surfaces of the placeholders 120, the shallow trench isolation layer 122, the backside spacer plugs 165PX and 165PY, the first dielectric pillar 140A, and the second dielectric pillar 140B. The backside interlayer dielectric layer 175 is in contact with multiple sides of the first and second dielectric pillars 140A, 140B. The backside interlayer dielectric layer 175 is in further contact with multiple sides of the dielectric plugs 165PX and 165PY. The dielectric plug 165PX (X-axis misalignment) is located between one of the placeholders 120 and backside interlayer dielectric layer 175 from the perspective of the cross-section X and the backside spacer plug 165PY (Y-axis misalignment) is between the backside interlayer dielectric layer 175 and the first dielectric pillar 140A from the perspective of the cross-section Y1.

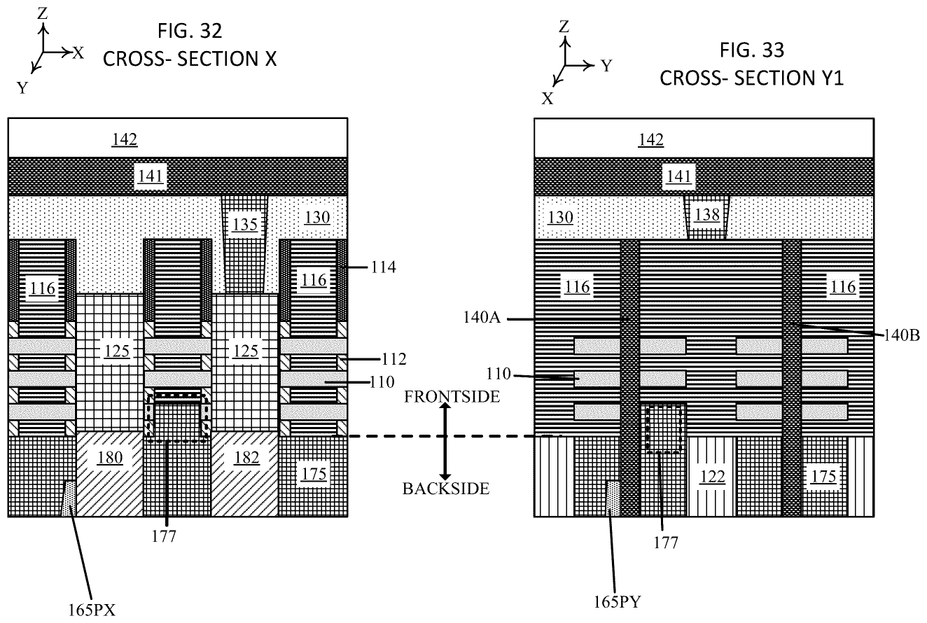

FIGS. 32, 33, and 34 illustrate the processing stage after removal of the placeholders 120 and formation of the backside contacts 180, 182, 184, 186, 188. The placeholders 120 are removed to expose the backside surfaces of the first source/drains 125 and the second source/drains 127. A metallization process fills the space of the removed placeholders 120 with a conductive metal to form the backside contacts 180, 182, 184, 186, 188. The dielectric plug 165PX (X-axis misalignment) is located between one of the backside contact 180 and backside interlayer dielectric layer 175 from the perspective of the X cross-section and the backside spacer plug 165PY (Y-axis misalignment) is between the backside interlayer dielectric layer 175 and the first dielectric pillar 140A from the perspective of the Y1 cross-section.

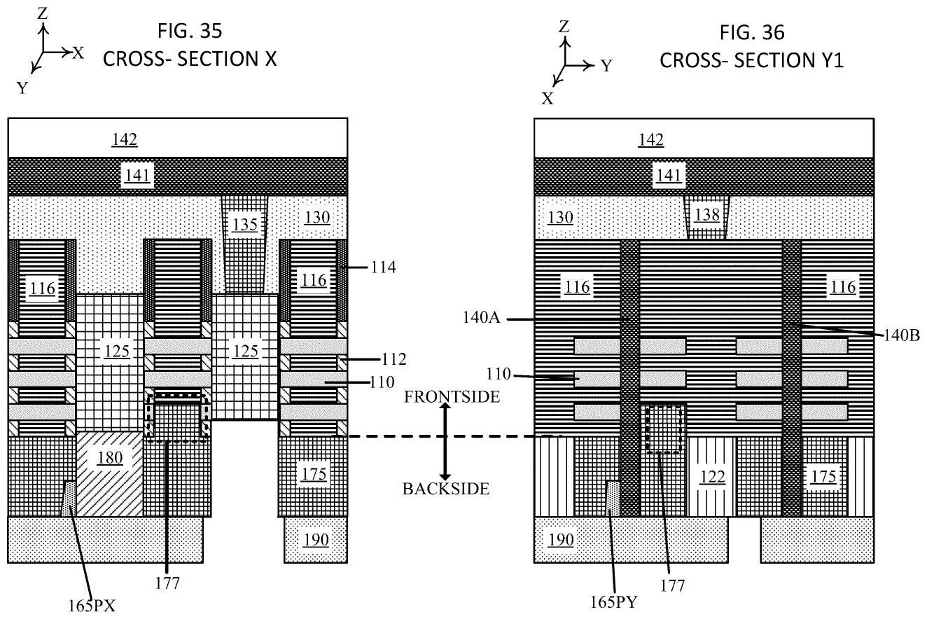

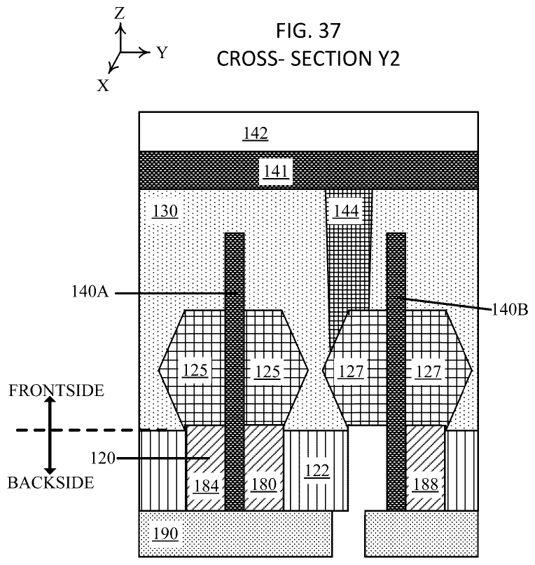

FIGS. 35, 36, and 37 illustrate the processing stage after formation and patterning of a lithography layer 190 and the removal of one or more backside contacts 182, 186. A lithography layer 190 is formed on exposed backside surfaces of the backside interlayer dielectric layer 175, backside spacer plugs 165PX, 165PY, the first and second dielectric pillars 140A, 140B, shallow trench isolation layer 122, and on the backside surface of the backside contacts 180, 182, 184, 186, 188. The lithography layer 190 is patterned to expose the backside surface of one or more of the backside contacts 182, 186. FIG. 37 illustrates the situation where the patterning of the lithography layer 190 is misaligned but a portion of the backside surface of backside contact 186 is exposed. The one or more backside contacts 182, 186 that were exposed are based on if the source/drain 125, 127 has a frontside contact or not. The one or more exposed backside contacts 182, 186 are removed to expose the backside surface of the first and second source/drains 125, 127.

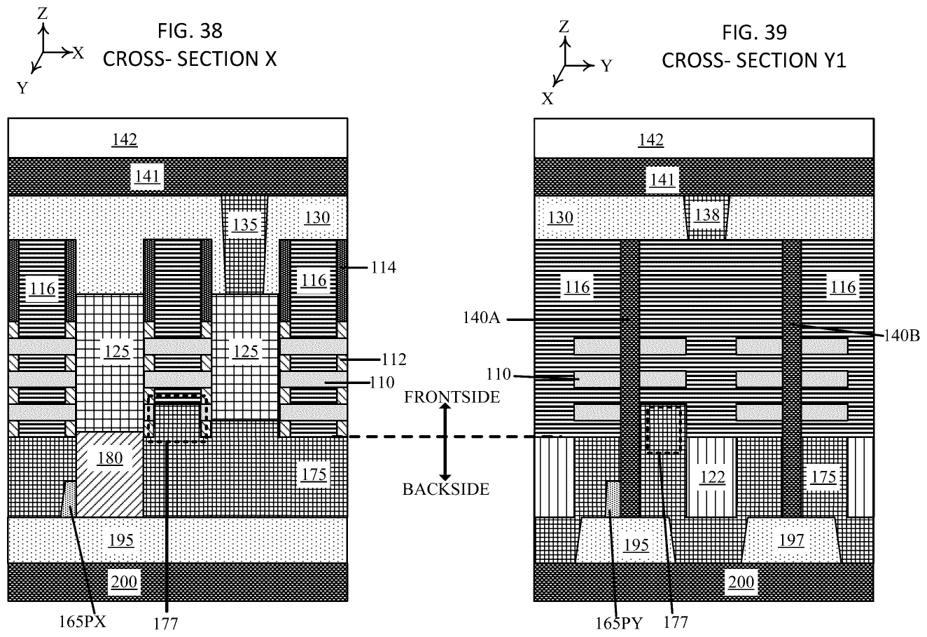

FIGS. 38, 39, and 40 illustrate the processing stage after additional backside processing. The lithography layer 190 is removed. The height of the backside interlayer dielectric layer 175 is increased by adding additional material so that the backside interlayer dielectric layer 175 extends over the backside contacts 180, 184, 188. The additional dielectric material also fills in the empty space created by the removal of the one or more backside contacts 182, 186. Trenches (not shown) are formed in the backside interlayer dielectric layer 175 and a metallization process fills these trenches (not shown) in with a conductive metal to form one or more metal lines 195, 197. The one or more metal lines 195, 197 can be a power line (VSS, VDD), a ground, a clock line, a signal line, or a different type of line. A backside interconnect 200 is formed on the backside interlayer dielectric layer 175 and the one or more metal lines 195, 197. The backside interconnect 200 can be comprised of one or more layers, one or more metal lines, one or more vias, or any combination thereof. The backside spacer plugs 165PX and 165PY have a relatively small width and height. The height and width of the backside spacer plugs 165PX and 165PY is controlled by how severe the misalignment was. The backside spacer plug 165PX extends partly up a vertical sidewall of the backside contact 180. Furthermore, the backside interlayer dielectric layer 175 can be in contact with a vertical side surface and maybe a horizontal side surface of the backside spacer plug 165PX. The backside spacer plug 165PY extends partly up a vertical sidewall of the first dielectric pillar 140A. Furthermore, the backside interlayer dielectric layer 175 can be in contact with a vertical side surface and maybe a horizontal side surface of the backside spacer plug 165PY.

The backside spacer plug 165PX is located on a first side of the backside contact 180 and the removed channel layer 110 is located on a second side of the backside contact 180, wherein the first side is opposite the second side. Furthermore, the depth of the backside interlayer dielectric layer 175 is different on the first side and the second side of the backside contact 180, such that the depth/height/dimension of the backside interlayer dielectric layer 175 is larger on the second side of the backside contact 180.

The backside spacer plug 165PY is located on a first side of the first dielectric pillar 140A and the removed channel layer 110 is located on a second side of the first dielectric pillar 140A, wherein the first side is opposite the second side. Furthermore, the depth of the backside interlayer dielectric layer 175 is different on the first side and the second side of the first dielectric pillar 140A, such that the depth/height/dimension of the backside interlayer dielectric layer 175 is larger on the second side of the first dielectric pillar 140A.

FIG. 14-40 illustrate the situation where the there was a misalignment in the X-axis and the Y-axis and the formation of the backside spacer plugs 165PX, 165PY to correct for misalignment. However, it is understood by one ordinary skill in the art that misalignment does not have to occur simultaneously in both the X-axis and the Y-axis. The misalignment could occur in only one axis, i.e., X-axis or Y-axis, such that only one backside spacer plug 165PX or 165PY would be needed to fix the misalignment in one access. The Figures illustrate the situation where there was dual misalignment for the simply illustrating both backside spacer plugs 165PX, 165PY. Therefore, the figures of the present application support a first scenario when there was a misalignment in the X-axis but not the Y-axis and a second scenario where there was a misalignment in the Y-axis but not the X-axis. The first scenario will support the formation of the backside spacer plug 165PX without the formation of the backside spacer plug 165PY and the second scenario will support the formation of the backside spacer plug 165PY without the formation of the backside spacer plug 165PX.

A microelectronic structure that includes a forksheet nanosheet transistor that includes a source/drain 125 a backside contact 180 located on the backside surface of the source/drain 125 and a backside spacer plug 165PX located on a first side of the backside contact 180.

A backside interlayer dielectric layer 175 that is in contact with a second side of the backside contact 180. The backside interlayer dielectric layer 175 is also in contact with the first side of the backside contact 180. The backside interlayer dielectric layer 175 is in contact with a side surface of the backside spacer plug 165PX.

The forksheet nanosheet transistor further includes a plurality of end portions of a channel layer 110, and a plurality of inner spacers 112. One of the plurality of inner spacer 112 is located above and below each of the end portions of the channel layer 110. The backside interlayer dielectric layer 175 is located between the end portions of the channel layers 110.

The backside interlayer dielectric layer 175 has a first thickness on the first side of the backside contact and the backside interlayer dielectric layer has a second thickness on the second side of the backside contact (see, for example, FIG. 38) and the second thickness is larger than the first thickness.

A microelectronic device includes a forksheet nanosheet transistor that includes a source/drain 125, a plurality of first channel layers 110 and a plurality of second channel layers 110. A dielectric pillar 140A located between the plurality of first channel layers 110 and the plurality of second channel layers 110 (see, for example, FIG. 39). A backside contact 180 located on the backside surface of the source/drain 125. A backside spacer plug 165PY located on a first side of the dielectric pillar 140A.

A backside interlayer dielectric layer 175 that is in contact with a second side of the dielectric pillar 140A. The backside interlayer dielectric layer 175 is also in contact with the first side of the dielectric pillar 140A. The backside interlayer dielectric layer 175 is in contact with a side surface of the backside spacer plug 165PY. The backside interlayer dielectric layer 175 is located between the second side of the dielectric pillar 140A and a gate 116 of the forksheet nanosheet transistor.

The backside interlayer dielectric layer 175 has a first thickness on the first side of the dielectric pillar 140A and the backside interlayer dielectric layer 175 has a second thickness on the second side of the dielectric pillar 140A (see, for example, FIG. 39), where the second thickness is larger than the first thickness.

A microelectronic device includes a forksheet nanosheet transistor that includes a source/drain 125, a plurality of first channel layers 110 and a plurality of second channel layers 110. A dielectric pillar 140A located between the plurality of first channel layers 110 and the plurality of second channel layers 110. A backside contact 180 located on the backside surface of the source/drain 125. A backside spacer plug 165PX located on a first side of the backside contact 180 and a second backside spacer plug 165PY located on a first side of the dielectric pillar 140A.

A backside interlayer dielectric layer 175 that is in contact with a second side of the dielectric pillar 140A and the second side of the backside contact 180. The backside interlayer dielectric layer 175 is also in contact with the first side of the dielectric pillar and the first side of the backside contact.

The backside interlayer dielectric layer 175 is in contact with a side surface of the first backside spacer plug 165PX and in contact with a side surface of the second backside spacer plug 165PY. The backside interlayer dielectric layer 175 is located between the second side of the dielectric pillar 140A and a gate 116 of the forksheet nanosheet transistor.

The plurality of second channel layers 110 includes a plurality of end portions of a channel layer 110, and a plurality of inner spacers 112. One of the plurality of inner spacer 112 is located above and below each of the end portions of the channel layer 110. The backside interlayer dielectric layer 175 is located between the end portions of the channel layers 110.

The backside interlayer dielectric layer 175 has a first thickness on the first side of the backside contact 180 and the backside interlayer dielectric layer 175 has a second thickness on the second side of the backside contact 180, where the second thickness is larger than the first thickness.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a forksheet nanosheet transistor that includes a source/drain;
a backside contact located on the backside surface of the source/drain; and
a backside spacer plug located on a first side of the backside contact.

2. The microelectronic structure of claim 1, further comprising:
a backside interlayer dielectric layer that is in contact with a second side of the backside contact.

3. The microelectronic structure of claim 2, wherein the backside interlayer dielectric layer is also in contact with the first side of the backside contact.

4. The microelectronic structure of claim 3, wherein the backside interlayer dielectric layer is in contact with a side surface of the backside spacer plug.

5. The microelectronic structure of claim 3, wherein the forksheet nanosheet transistor further includes a plurality of end portions of a channel layer, and a plurality of inner spacers, wherein one of the plurality of inner spacer is located above and below each of the end portions of the channel layer.

6. The microelectronic structure of claim 5, wherein the backside interlayer dielectric layer is located between the end portions of the channel layers.

7. The microelectronic structure of claim 3, wherein the backside interlayer dielectric layer has a first thickness on the first side of the backside contact and the backside interlayer dielectric layer has a second thickness on the second side of the backside contact, wherein the second thickness is larger than the first thickness.

8. A microelectronic structure comprising:
a forksheet nanosheet transistor that includes a source/drain, a plurality of first channel layers and a plurality of second channel layers;
a dielectric pillar located between the plurality of first channel layers and the plurality of second channel layers;
a backside contact located on the backside surface of the source/drain; and
a backside spacer plug located on a first side of the dielectric pillar.

9. The microelectronic structure of claim 8, further comprising:
a backside interlayer dielectric layer that is in contact with a second side of the dielectric pillar.

10. The microelectronic structure of claim 9, wherein the backside interlayer dielectric layer is also in contact with the first side of the dielectric pillar.

11. The microelectronic structure of claim 10, wherein the backside interlayer dielectric layer is in contact with a side surface of the backside spacer plug.

12. The microelectronic structure of claim 10, wherein the backside interlayer dielectric layer is located between the second side of the dielectric pillar and a gate of the forksheet nanosheet transistor.

13. The microelectronic structure of claim 10, wherein the backside interlayer dielectric layer has a first thickness on the first side of the dielectric pillar and the backside interlayer dielectric layer has a second thickness on the second side of the dielectric pillar, wherein the second thickness is larger than the first thickness.

14. A microelectronic structure comprising:
a forksheet nanosheet transistor that includes a source/drain, a plurality of first channel layers and a plurality of second channel layers;
a dielectric pillar located between the plurality of first channel layers and the plurality of second channel layers;
a backside contact located on the backside surface of the source/drain;
a backside spacer plug located on a first side of the backside contact; and
a second backside spacer plug located on a first side of the dielectric pillar.

15. The microelectronic structure of claim 14, further comprising:
a backside interlayer dielectric layer that is in contact with a second side of the dielectric pillar and the second side of the backside contact.

16. The microelectronic structure of claim 15, wherein the backside interlayer dielectric layer is also in contact with the first side of the dielectric pillar and the first side of the backside contact.

17. The microelectronic structure of claim 16, wherein the backside interlayer dielectric layer is in contact with a side surface of the first backside spacer plug and in contact with a side surface of the second backside spacer plug.

18. The microelectronic structure of claim 15, wherein the backside interlayer dielectric layer is located between the second side of the dielectric pillar and a gate of the forksheet nanosheet transistor.

19. The microelectronic structure of claim 15, wherein the plurality of second channel layers includes a plurality of end portions of a channel layer, and a plurality of inner spacers, wherein one of the plurality of inner spacer is located above and below each of the end portions of the channel layer, wherein the backside interlayer dielectric layer is located between the end portions of the channel layers.

20. The microelectronic structure of claim 15, wherein the backside interlayer dielectric layer has a first thickness on the first side of the backside contact and the backside interlayer dielectric layer has a second thickness on the second side of the backside contact, wherein the second thickness is larger than the first thickness.
